(19) United States
(12) Patent Application Publication
(10) Pub. No.: US 2020/0051880 A1
(43) Pub. Date: Feb. 13, 2020

(54) SEMICONDUCTOR DEVICE COMPRISING A RECESS AND METHOD OF FABRICATING THE SAME

(71) Applicant: Infineon Technologies AG, Neubiberg (DE)

(72) Inventors: Thomas Bemmerl, Schwandorf (DE); Michael Stadler, Muenchen (DE)

(73) Assignee: Infineon Technologies AG, Neubiberg (DE)

(21) Appl. No.: 16/519,706

(22) Filed: Jul. 23, 2019

(30) Foreign Application Priority Data
Aug. 10, 2018 (DE) 10 2018 119 522.2

(51) Int. Cl. H01L 23/13; H01L 23/00

(52) U.S. Cl. CPC H01L 23/13; H01L 24/32; H01L 24/83; H01L 2224/32225; H01L 2224/83801; H01L 2224/8385; H01L 2224/32245; H01L 2224/83385

(57) ABSTRACT

A semiconductor device is disclosed. In one example, the semiconductor device comprises a die carrier comprising an X-shaped recess on a first surface of the die carrier; a semiconductor die arranged over the first surface of the die carrier and at least partly covering the X-shaped recess; and a coupling agent attaching the semiconductor die to the die carrier, wherein the coupling agent is at least partially arranged in the X-shaped recess. Each of the four arms of the X-shaped recess points towards a corner of the semiconductor die and extends over an outline of the semiconductor die in an orthogonal projection onto the first surface of the die carrier.

### CROSS-REFERENCE TO RELATED APPLICATION

This Utility Patent Application claims priority to German Patent Application No. 10 2018 119 522.2, filed Aug. 10, 2018, which is incorporated herein by reference.

### TECHNICAL FIELD

This disclosure pertains to a semiconductor device comprising a recess and to a method for fabricating such a semiconductor device.

### BACKGROUND

A semiconductor device may comprise a substrate also called a die carrier and a semiconductor that is attached to the die carrier by a coupling agent like a (soft) solder or an adhesive. Ideally the semiconductor die is attached to the die carrier such that its backside or bottom side (the side facing the die carrier) is completely covered by the coupling agent, such that a bleedout of coupling agent is minimal, such that a stress induced into the semiconductor die by the solidified coupling agent is minimal, such that the solidified coupling agent comprises a minimum of voids and such that a tilt of the semiconductor die relative to the die carrier is minimal. Deviations from these requirements may e.g. result in a semiconductor device that exhibits sub-optimum electrical, thermal or mechanical characteristics, in a deficient device or in a device with a reduced life time.

### SUMMARY

A first aspect of the disclosure pertains to a semiconductor device that comprises a die carrier comprising an X-shaped recess on a first surface of the die carrier, a semiconductor die arranged over the first surface of the die carrier and at least partly covering the X-shaped recess and a coupling agent attaching the semiconductor die to the die carrier, wherein the coupling agent is at least partially arranged in the X-shaped recess, wherein each of the four arms of the X-shaped recess points towards a corner of the semiconductor die and extends over an outline of the semiconductor die in an orthogonal projection onto the first surface of the die carrier.

A second aspect of the disclosure pertains to a semiconductor device that comprises a die carrier comprising an X-shaped recess on a first surface of the die carrier, a semiconductor die arranged over the first surface of the die carrier and at least partly covering the X-shaped recess and a coupling agent attaching the semiconductor die to the die carrier, wherein each of the four arms of the X-shaped recess points towards a corner of the semiconductor die and wherein a main portion of each arm of the X-shaped recess is formed by straight sides of the respective arm.

A third aspect of the disclosure pertains to a method for fabricating a semiconductor device, wherein the method comprises providing a die carrier comprising an X-shaped recess on a first surface of the die carrier, depositing a coupling agent over a center of the X-shaped recess and attaching a semiconductor die to the deposited coupling agent, wherein each of the four arms of the X-shaped recess points towards a corner of the semiconductor die and extends over an outline of the semiconductor die in an orthogonal projection onto the first surface of the die carrier.

### BRIEF DESCRIPTION OF THE DRAWINGS

The accompanying drawings illustrate examples and together with the description serve to explain principles of the disclosure. Other examples and many of the intended advantages of the disclosure will be readily appreciated as they become better understood by reference to the following detailed description. The elements of the drawings are not necessarily to scale relative to each other. Like reference numerals designate corresponding similar parts.

FIG. 1 comprises FIGS. 1A-1C and shows in FIGS. 1A and 1B top-down views of semiconductor devices and in FIG. 1C a sectional view of the semiconductor device of FIG. 1A.

FIG. 2 shows a perspective view of a die carrier that may be comprised in a semiconductor device like the ones shown in FIGS. 1A-1C.

FIG. 3 shows a further die carrier and a semiconductor die with a non-quadratic rectangular shape that may be comprised in a semiconductor device like the ones shown in FIGS. 1A-1C.

FIG. 4 comprises FIGS. 4A-4C and shows in FIGS. 4A and 4B a semiconductor device in various stages of fabrication. FIG. 4C schematically shows the directions into which a coupling agent is pressed when a semiconductor die is pressed down onto a die carrier.

FIG. 5 schematically shows how parts of a recess in the die carrier that protrude beyond an outline of the semiconductor die may act as outgassing channels.

FIG. 6 shows a flow diagram of a method for fabricating a semiconductor device.

### DETAILED DESCRIPTION

The semiconductor chip(s) described further below may be of different types, may be manufactured by different technologies and may include for example integrated electrical, electro-optical or electro-mechanical circuits and/or passives, logic integrated circuits, control circuits, microprocessors, memory devices, etc.

The die carriers described below may be (permanent) device carriers used for packaging. The carriers may comprise or consist of any sort of material as, for example, ceramic or metallic material, copper or copper alloy or iron/nickel alloy. The carrier can be connected mechanically and electrically with one contact element of the semiconductor chip(s). The semiconductor chip(s) can be connected to the carrier by soldering or adhering by means of an adhesive.

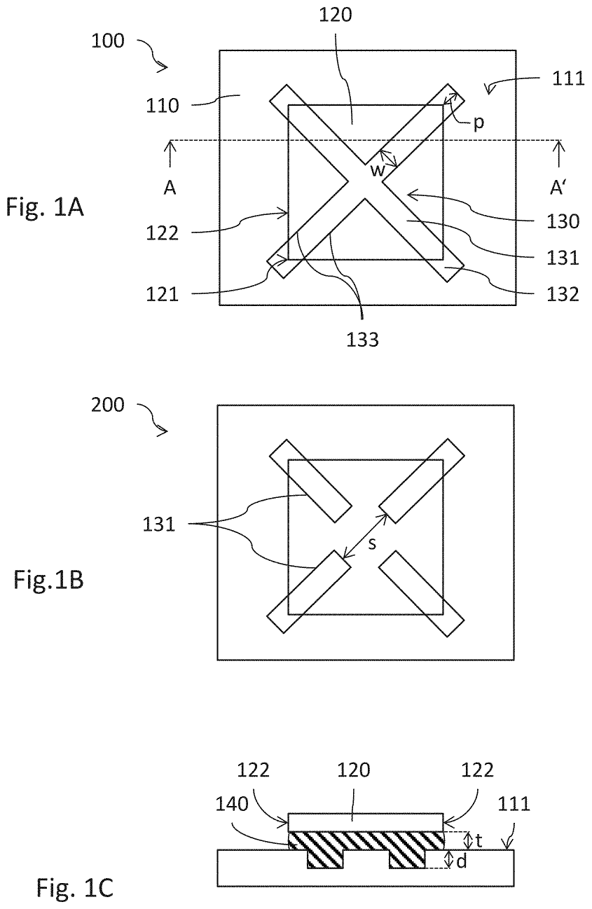

FIG. 1A shows a top-down view of a semiconductor device 100 that comprises a die carrier 110 and a semiconductor die 120 arranged over a first surface 111 of the die carrier 110. The semiconductor die 120 is attached to the first surface 111 of the die carrier 110 by a coupling agent 140 (compare FIG. 1C).

The die carrier 110 comprises an X-shaped recess 130 arranged on the first surface 111. The semiconductor die 120 is arranged over the first surface 111 such that it at least partly covers the X-shaped recess. The semiconductor die 120 is arranged over the first surface 111 such that each of the four arms 131 of the X-shaped recess 130 points towards a corner 121 of the semiconductor die 120.

The die carrier 110 may e.g. have approximately the same lateral dimensions as the semiconductor chip 120, or it may e.g. be about twice as large, three times as large, or even larger than the semiconductor die 120.

The X-shaped recess 130 may be dimensioned such that each of the four arms 131 extends over an outline 122 of the semiconductor die 120 in an orthogonal projection onto the first surface 111 of the die carrier 110. In particular, a protruding part 132 of each of the four arms 131 may be exposed at the outline 122.

The semiconductor die 120 may be arranged over the X-shaped recess 130 such that the center of the semiconductor die 120 and the center of the X-shaped recess 130 coincide in an orthogonal projection onto the first surface 111 of the die carrier 110. The semiconductor die 120 may be any kind of die, e.g. a power die, a logic die, a transistor etc.

The die carrier 110 may comprise or consist of metal, a metal alloy, a plastic, or a laminate. The die carrier 110 may e.g. be (part of) a leadframe, a DCB (direct copper bond), a DAB (direct aluminum bond), an AMB (active metal brazing) substrate.

According to an example, the die carrier 110 may be any stable part known in the art that is configured to carry a semiconductor die.

The coupling agent 140 may be arranged partly or completely within the outline 122 under the semiconductor chip 120. According to an example, the coupling agent 140 may extend slightly beyond the outline 122 on the first surface 111. The coupling agent 140 is at least partially arranged in the X-shaped recess 130. The coupling agent 140 may be a solder, e.g. a soft solder, or an adhesive, e.g. a conductive paste or a non-conductive paste. The coupling agent 140 may be configured to electrically couple an electrode on the bottom side of the semiconductor die 120 to the die carrier 110.

A width w of the X-shaped recess 130 (in particular, a width w of the four arms 131 of the X-shaped recess 130) may be smaller or greater than 50 μm, greater than 100 μm, greater than 300 μm, greater than 500 μm, greater than 700 μm, greater than 1 mm, or even greater than 2 mm. A depth d of the X-shaped recess 130 (compare FIG. 1C) may be in the range of 20 μm to 100 μm, in particular about 40 μm, about 60 μm, or about 80 μm. The depth d may also be greater than 100 μm. The protruding parts 132 may protrude a minimum protruding distance p of at least 50 μm, at least 100 μm, or at least 200 μm.

According to an example, the X-shaped recess 130 covers at least 10%, or at least 30%, or at least 50% of the area under the outline 122 of the semiconductor chip 120.

According to an example, at least a main portion of each arm 131 of the X-shaped recess 130 is formed by straight sides 133 of the respective arm 131 as shown in FIG. 1A. The straight sides 133 may in particular be straight over at least a range of 50%-100% of the length of the respective arm as e.g. shown in FIG. 1A. According to an example, the straight sides 133 may be parallel straight sides as also shown in FIG. 1A.

The semiconductor device 100 may further comprise an encapsulation body (not shown) encapsulating the semiconductor die 120. The encapsulation body may comprise or consist of a mold. The encapsulation body may be arranged over the first surface 111 of the die carrier 110 and it may fill the protruding parts 132 of the X-shaped recess 130 (at least insofar as the protruding parts 132 are not filled with the coupling agent 140). FIG. 1B shows a top-down view of a further semiconductor device 200 which may be identical to the semiconductor device 100 except for the differences described below.

In the example of semiconductor device 100 shown in FIG. 1A, the four arms 131 of the X-shaped recess 130 are connected at the center of the X-shaped recess 130. In the example of semiconductor device 200 of FIG. 1B the four arms 131 are unconnected at the center of the X-shaped recess 130. A spacing s between opposing arms 131 may be about 20 μm, about 50 μm, about 100 μm, about 200 μm, about 500 mm, about 1 mm, or even more than 1 mm.

FIG. 1C shows a side view of the semiconductor device 100 of FIG. 1A along the line A-A′. The semiconductor chip 120 may be arranged on the die carrier 110 such that the semiconductor chip 120 and the first surface 111 are mostly or even completely parallel. In other words, the semiconductor chip 120 may be arranged on the die carrier 110 without any tilt or at least without any significant tilt.

The coupling agent 140 may completely fill the X-shaped recess 130, at least below the outline 122 of the semiconductor chip 120. Side faces 123 of the semiconductor chip 120 may be free of the coupling agent 140 or the coupling agent 140 may at least partially cover the side faces 123.

The depth d may be identical or at least substantially identical over the whole X-shaped recess 130. According to an example, the depth may be smaller at the end of each arm 131 (at the protruding parts 132) than in the rest of the X-shaped recess. This may be due to the fabrication process of the X-shaped recess 130.

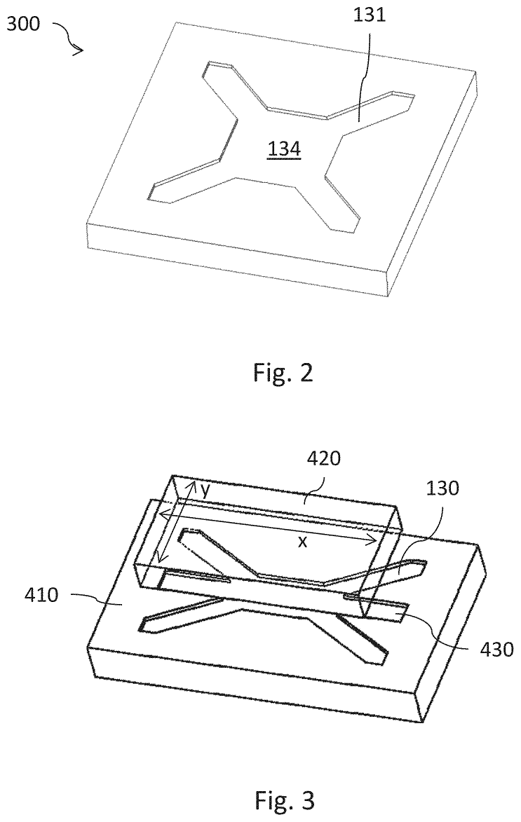

FIG. 2 shows a perspective view of a die carrier 300 which may be identical to the die carrier 110 except for the differences mentioned below.

In die carrier 300 the X-shaped recess comprises the four arms 131 and a basin 134 arranged at the center of the four arms 131. The basin 134 and the four arms 131 may have an identical depth d. The basin 134 may have any suitable lateral dimensions, for example in the range of 100 μm to 5 mm or even more. The basin 134 may e.g. have a rectangular, quadratic or round shape, seen from above. In the case that the basin 134 has a rectangular or quadratic shape, the four arms 131 may extend from the corners of the basin 134 as shown in FIG. 2.

The basin 134 may be dimensioned such that only a part of the area below the semiconductor chip 120 is occupied by the basin 134, e.g. approximately 10%, 30%, or 50%.

FIG. 3 shows a perspective view of a further example of a die carrier 410 and a semiconductor chip 420 which may be identical to the die carrier 110 and semiconductor chip 120, respectively, except for the differences described below.

The semiconductor chip 420 may have a rectangular non-quadratic footprint, wherein the length x is greater than the width y of the semiconductor chip 420. In particular, the semiconductor chip 420 may have a high aspect ratio (x:y) of about 1.5:1, or 2:1, or 3:1, or even more.

The die carrier 410 comprises the X-shaped recess 130 and additionally a bar-shaped recess 430 which extends from the center of the X-shaped recess 130 in parallel to the longer sides of the non-quadratic semiconductor die 420. The bar-shaped recess 430 may extend beyond the outline of the semiconductor die 420, analogously to the X-shaped recess 130. The X-shaped recess 130 and the bar-shaped recess 430 may have an identical depth d and/or an identical width w. However, the X-shaped recess 130 and the bar-shaped recess 430 may also have a different depth and/or a different width.

According to an example, the die carrier 410 may additionally comprise the basin 134, wherein the bar-shaped recess extends from opposing side faces of the basin 134.

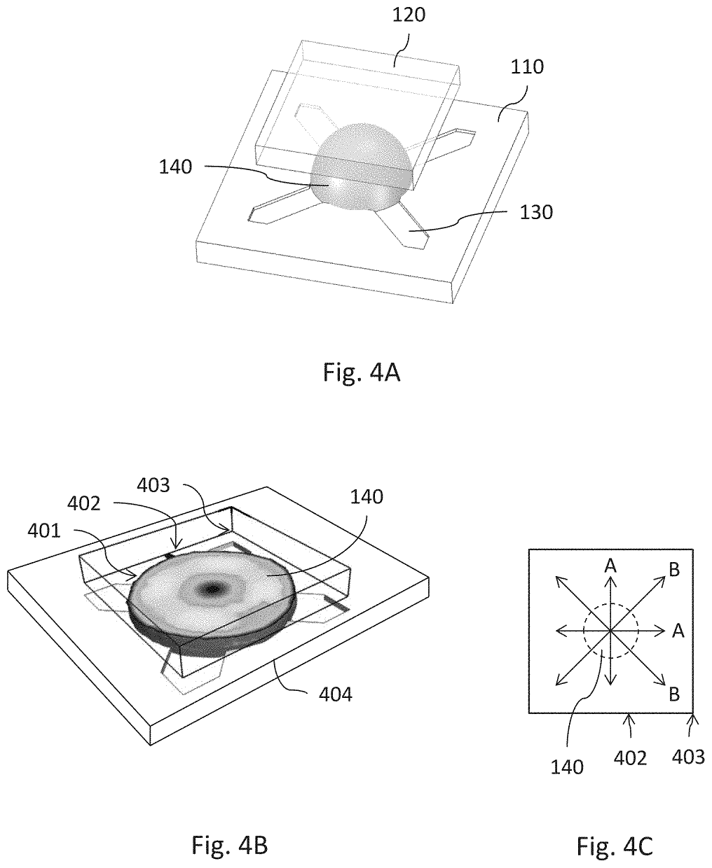

As shown in FIG. 4A, attaching the semiconductor chip 120 to the die carrier 110 may comprise depositing the coupling agent 140, in particular a single droplet of the coupling agent 140, on the first surface 111 of the die carrier 110. In order to deposit the coupling agent 140 and/or in order to attach the semiconductor die 120, the coupling agent 140 may be liquefied by an energy input, for example by heating. The coupling agent 140 may be deposited over the center of the X-shaped recess 130. In the case that the die carrier 110 comprises the basin 134, the coupling agent 140 may be deposited over the basin 134.

Subsequently, the semiconductor die 120 may be arranged over the deposited coupling agent 140 (compare FIG. 4A), e.g. by a pick-and-place process, and pressed down onto the deposited coupling agent 140. The semiconductor die 120 may be pressed down with a predefined amount of force.

As shown in FIG. 4B, the coupling agent 140 is squeezed outwards from the point of deposition by the downwards movement of the semiconductor die 110. The semiconductor die 110 may be pressed down until the coupling agent 140 completely or almost completely covers the bottom side of the semiconductor die 110.

As the coupling agent 140 is being squeezed out, it may have an essentially circular shape as seen from above (compare FIG. 4B). On an essentially flat die carrier this causes the flow front 401 of the coupling agent 140 to reach the edges 402 of the semiconductor die 120 sooner than the corners 403 of the semiconductor die 120. In other words, the velocity of the coupling agent 140 being squeezed out is isotropic in the direction A towards the edges 402 and in the direction B towards the corners 403 (compare FIG. 4C). This may cause an undesirable amount of bleedout of the coupling agent 140 along the edges 402.

The X-shaped recess 130 may act as a guiding structure for the coupling agent 140 being squeezed out and may cause an increase of the velocity in the direction A towards the corners 403 relative to the velocity in the direction B towards the edges 402. Therefore, bleedout of the coupling agent 140 may be reduced or even prevented entirely. The fact that a main portion of each arm 131 may be formed by straight sides of the respective arm 131 (in particular by sides that are straight over at least a range of 50%-100% of the length of the respective arm) may improve the effectiveness of the X-shaped recess as such a guiding structure because corrugations in the outline of the arms 131 would act as “speed bumps” for the coupling agent 140.

Due to the acceleration of the coupling agent 140 in the direction A relative to the direction B the whole backside of the semiconductor die 120 may be wetted (even at the corners 403) by the coupling agent 140 (and therefore the whole backside of the semiconductor die 120 may be attached to the die carrier 110). The bond line thickness t of the coupling agent 140 (compare FIG. 1C) may therefore have a non-zero minimum value. The bond line thickness t may e.g. have a minimum value of 10 μm, 30 μm, 50 μm, 100 μm, 200 μm or more.

The reduced bleedout of the coupling agent 140 out of the outline 122 of the semiconductor die 120 may enable a reduction of the minimal required distance between the outline 122 of the semiconductor die 120 and an edge 404 of the die carrier 110. This may reduce the overall size of semiconductor device 100 or 200.

The guiding effect of the X-shaped recess 130 on the coupling agent 140 may make it unnecessary to use a spanking tool to pre-flatten the droplet of coupling agent 140 as shown in FIG. 4A prior to pressing the semiconductor die 110 onto the droplet.

The symmetrical profile of the X-shaped recess 130 as seen from above may cause a symmetrical distribution of pressure in the droplet of coupling agent 140 as it is compressed by the semiconductor die 120 being pressed down. This symmetrical distribution of the pressure around the center of the droplet entails a tilt-free or nearly tilt-free orientation of the semiconductor die 120 on the first surface 111 of the die carrier.

In the case of a non-quadratic rectangular semiconductor chip 420 as shown in FIG. 3 the bar-shaped recess 430 may similarly act as a guiding structure that causes an increase of the velocity along the longer side x relative to the velocity along the shorter side y of the semiconductor chip 420.

The basin 134 may help to dampen turbulences in the flow of the coupling agent 140 during compression. This may result in a more homogenous distribution of the coupling agent 140 over the complete bottom surface of the semiconductor die 120.

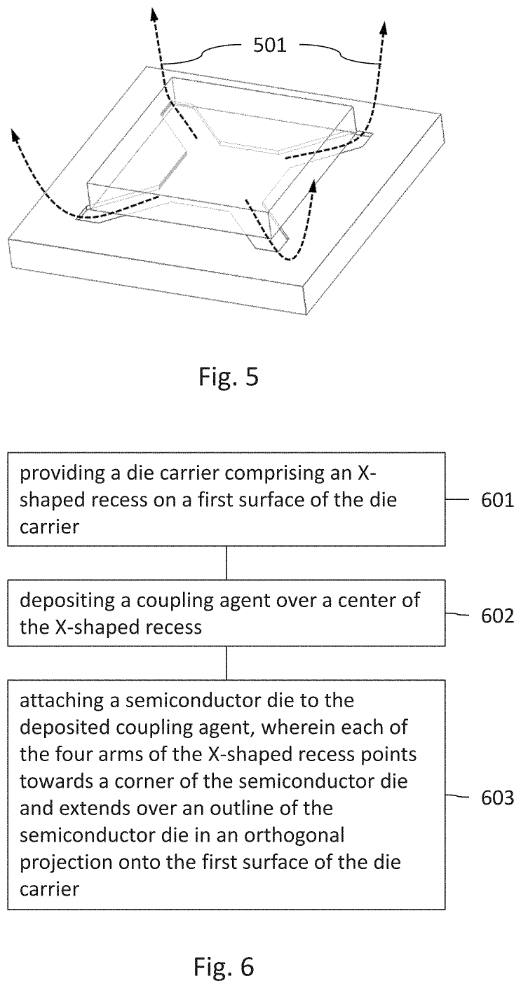

The coupling agent 140 may comprise a fluxing agent which may be evaporated (e.g. by heating) when attaching the semiconductor die 120 to the die carrier 110. Such an evaporation process turns the liquid flux into gases that have to diffuse out from the coupling agent 140 under the semiconductor die 120. Due to the protruding parts 132, the arms 131 of the X-shaped recess 130 may act as channels that enable an efficient diffusion of such gases out of the coupling agent 140 as indicated by the arrows 501 in FIG. 5.

Arms of a recess that do not protrude beyond the outline 122 of the semiconductor chip 120 would not be able to act as outgassing channels.

According to an example, a main portion of each arm 131 of the X-shaped recess 130 is formed by straight sides 133 of the respective arm 131. In particular, a main portion of each arm 131 may be formed by sides 133 that are straight over at least a range of 50%-100% of the length of the respective arm. In this way, gases may be removed more efficiently from the coupling agent 140 because gas bubbles may stick to any form of corrugation in the channels due to surface tension.

Efficiently removing gases may reduce voids in the coupling agent 140 and may therefore improve the adhesion of the semiconductor die 120 to the die carrier 110.

FIG. 6 shows a flow diagram of a method 600 for fabricating a semiconductor device like the semiconductor devices 100 and 200. The method 600 comprises a first act 601 of providing a die carrier comprising an X-shaped recess on a first surface of the die carrier, a second act 602 of depositing a coupling agent over a center of the X-shaped recess and a third act 603 of attaching a semiconductor die to the deposited coupling agent, wherein each of the four arms of the X-shaped recess points towards a corner of the semiconductor die and extends over an outline of the semiconductor die in an orthogonal projection onto the first surface of the die carrier.

According to an example of the method 600 a dispersion of the coupling agent in the X-shaped recess towards the corners of the semiconductor die is accelerated compared to a dispersion of the coupling agent outside of the X-shaped recess.

According to an example of the method 600 the four arms of the X-shaped recess extend beyond an outline of the semiconductor die in an orthogonal projection onto the first surface of the die carrier, wherein the method 600 further comprises outgassing the coupling agent through the four arms of the X-shaped recess.

According to an example of the method 600 attaching the semiconductor die comprises pressing the semiconductor die onto the deposited coupling agent until the coupling agent completely covers a surface of the semiconductor die facing the die carrier.

According to an example of the method 600 depositing the coupling agent comprises depositing a solder of a soft solder wire, or a solder of a soft solder paste, or a glue.

According to an example of the method 600 the attaching is performed after the depositing without any further act, in particular an act of spanking the deposited coupling agent, in between. Furthermore, the act of attaching the semiconductor die may be performed immediately after depositing the coupling agent.

1. A semiconductor device, comprising:
a die carrier comprising an X-shaped recess on a first surface of the die carrier;
a semiconductor die arranged over the first surface of the die carrier and at least partly covering the X-shaped recess; and
a coupling agent attaching the semiconductor die to the die carrier, wherein the coupling agent is at least partially arranged in the X-shaped recess,
wherein each of the four arms of the X-shaped recess points towards a corner of the semiconductor die and extends over an outline of the semiconductor die in an orthogonal projection onto the first surface of the die carrier.

2. The semiconductor device of claim 1, wherein the die carrier comprises a rectangular recess arranged in the center of the X-shaped recess, wherein the arms of the X-shaped recess point from the rectangular recess to the corners of the semiconductor die.

3. The semiconductor device of claim 1, wherein a main portion of each arm of the X-shaped recess is formed by straight sides of the respective arm.

4. The semiconductor device of claim 1, wherein a footprint of the semiconductor die has a non-quadratic rectangular shape, and wherein the die carrier comprises a bar-shaped recess extending from the center of the X-shaped recess in parallel to the longer sides of the non-quadratic rectangular footprint of the semiconductor die.

5. The semiconductor device of claim 1, wherein each arm of the X-shaped recess extends at least 100 micrometer over the outline of the semiconductor die.

6. The semiconductor device of claim 1, wherein the X-shaped recess has a depth in a range from 20 micrometer to 100 micrometer.

7. The semiconductor device of claim 1, wherein a thickness of the coupling agent has a non-zero minimum value at the corners of the semiconductor die.

8. The semiconductor device of claim 1, wherein the coupling agent completely covers a surface of the semiconductor die facing the die carrier.

9. The semiconductor device of claim 1, wherein the arms of the X-shaped recess are connected at the center of the X-shaped recess.

10. The semiconductor device of claim 1, wherein the arms of the X-shaped recess are unconnected at the center of the X-shaped recess.

11. The semiconductor device of claim 1, wherein the die carrier comprises a leadframe, a laminate, a DCB, a DAB, or an AMB substrate.

12. The semiconductor device of claim 1, wherein the coupling agent comprises a solder.

13. The semiconductor device of claim 1, wherein the coupling agent comprises an adhesive.

14. A semiconductor device, comprising:
a die carrier comprising an X-shaped recess on a first surface of the die carrier;
a semiconductor die arranged over the first surface of the die carrier and at least partly covering the X-shaped recess; and
a coupling agent attaching the semiconductor die to the die carrier,
wherein each of the four arms of the X-shaped recess points towards a corner of the semiconductor die, and
wherein a main portion of each arm of the X-shaped recess is formed by straight sides of the respective arm.

15. A method for fabricating a semiconductor device, the method comprising:
providing a die carrier comprising an X-shaped recess on a first surface of the die carrier;
depositing a coupling agent over a center of the X-shaped recess; and
attaching a semiconductor die to the deposited coupling agent, wherein each of the four arms of the X-shaped recess points towards a corner of the semiconductor die and extends over an outline of the semiconductor die in an orthogonal projection onto the first surface of the die carrier.

16. The method of claim 15, wherein a dispersion of the coupling agent in the X-shaped recess towards the corners of the semiconductor die is accelerated compared to a dispersion of the coupling agent outside of the X-shaped recess.

17. The method of claim 15, wherein the four arms of the X-shaped recess extend beyond an outline of the semiconductor die in an orthogonal projection onto the first surface of the die carrier, and wherein the method further comprises outgassing the coupling agent through the four arms of the X-shaped recess.

18. The method of claim 15, wherein attaching the semiconductor die comprises pressing the semiconductor die onto the deposited coupling agent until the coupling agent completely covers a surface of the semiconductor die facing the die carrier.

19. The method of claim 15, wherein depositing the coupling agent comprises depositing a solder of a soft solder wire, or a solder of a soft solder paste, or a glue.

20. The method of claim 15, wherein the attaching is performed after the depositing without any further act, in particular an act of spanking the deposited coupling agent, in between.
